(19) United States
(12) Patent Application Publication
(10) Pub. No.: US 2025/0107243 A1
(43) Pub. Date: Mar. 27, 2025

(54) INTEGRATED CIRCUIT DEVICES WITH REPLICA CELLS AND FILLER CELLS FOR REDUCING LOCAL LAYOUT EFFECTS

(71) Applicant: Intel Corporation, Santa Clara, CA (US)

(72) Inventors: Burak Baylav, Hillsboro, OR (US); Prabhjot Luthra, Hillsboro, OR (US); Nidhi Khandelwal, Portland, OR (US); Marni Nabors, Portland, OR (US)

(73) Assignee: Intel Corporation, Santa Clara, CA (US)

(21) Appl. No.: 18/473,440

(22) Filed: Sep. 25, 2023

(51) Int. Cl. H01L 27/02; G06F 30/392; G06F 30/398; H01L 23/528

(52) U.S. Cl. CPC H10D 89/10; G06F 30/392; H01L 23/528; G06F 30/398

(57) ABSTRACT

An IC device may include functional regions as well as replica cells and filler cells that can reduce local layout effect in the IC device. A functional region includes functional cells, e.g., logic cell or memory cells. A white space may be between a first functional region and a second functional region. A first portion of the white space may be filled with replica cells, each of which is a replica of a cell in the first functional region. A second portion of the white space may be filled with filler cells that are not functional. The first function region is closer to the replica cells than to the filler cells. A third portion of the white space may be filled with replica cells, each of which is a replica of a cell in the second functional region. The second portion is between the first portion and the third portion.

### BACKGROUND

Local layout effects or layout-dependent effects are environmental effects that negatively impact the electrical characteristics of a semiconductor device due to its physical layout and proximity to other features on an integrated circuit. The physical environment in which a semiconductor device resides can vary its characteristics. For instance, the threshold voltage shift of a given device (e.g., a transistor) can be changed based on its neighborhood. Local layout effects may be caused by parasitic capacitance, parasitic resistance or parasitic inductance that exists between different elements in the circuit layout. Additionally or alternatively, local layout effects may be caused by mechanical stress introduced by nearby structures. Local layout effects can introduce unwanted coupling, delays, signal distortions, leading to performance degradation or even functional failures.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an integrated circuit (IC) device with replica cells and filler cells, according to some embodiments of the disclosure.

FIGS. 2A-2E illustrate a process of forming an IC device layout including replica cells and filler cells, according to some embodiments of the disclosure.

FIGS. 3A-3E illustrate another process of forming an IC device layout including replica cells and filler cells, according to some embodiments of the disclosure.

FIG. 4 illustrates an example cell, according to some embodiments of the disclosure.

FIGS. 5A and 5B illustrate another example cell, according to some embodiments of the disclosure.

FIGS. 6A and 6B are top views of a wafer and dies that may include one or more IC devices with replica cells and filler cells, according to some embodiments of the disclosure.

FIG. 7 is a side, cross-sectional view of an example IC package that may include one or more IC devices with replica cells and filler cells, according to some embodiments of the disclosure.

FIG. 8 is a cross-sectional side view of an IC device assembly that may include components having one or more IC devices with replica cells and filler cells, according to some embodiments of the disclosure.

FIG. 9 is a block diagram of an example computing device that may include one or more components with one or more IC devices with replica cells and filler cells, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Automated Place and Route (APR) tools are commonly used to place design blocks in a chip area for forming an IC device. A design block may be a block of functional cells, such as logic cells, memory cells, and so on. A logic cell may have one or more logic functions. A memory cell may have one or more storage functions. There can be gaps between the design blocks. Such gaps are referred to as “white space.” White space usually needs to be filled for various purposes, e.g., for meeting one or more density requirements, for establishing power continuity (e.g., power rain, VDD, or VSS continuity), for establishing N-well or P-well continuity, and so on. Functional cells in a design block can cause local layout effects in its neighboring design blocks. It is usually hard to accurately predict the electrical impact of local layout effects, hence minimizing local layout effects can be beneficial for achieving desirable performances of IC devices.

Embodiments of the present disclosure provide IC devices with replica cells and filler cells to reduce local layout effects. A replica cell is a cell that is formed by cloning or replicating a functional cell (e.g., a cell having a logic or storage function) in a design block but is placed outside the design block. For instance, the replica cell may abut an edge of the design block. With the replica cells, the local layout effect can be pushed to a region that is further from the design block. The region can be at least partially filled with filler cells. A filler cell is a non-functional cell, which may have no logic or storage function. Replica cells and fillers cells can be designed and formed based on a combination of design block integration methodology and whitespace fill methodology for providing additional protection against local layout effects.

In various embodiments of the present disclosure, an IC device includes a plurality of functional regions, each of which may include one or more logic cells, memory cells, other types of functional cells, or some combination thereof. A functional region may also be referred to as a functional block, active region, or active block. One or more near regions between two or more functional regions may be identified. Each near region may abut a functional region and include one or more replica cells, each of which is a replica of a cell in the functional region. A near region may include a replica of one or more rows of cells in the functional region. In some embodiments, the height of a near region may be no more than 2 micrometers. In an example, a near region may have a height that is the same or substantially similar to the height of a cell in the functional region. In addition to the one or more near regions, one or more far regions between the functional regions may be identified. Each function group is closer to a near region than to a far region. Each far region may include one or more filler cells. A filler cell may include one or more dummy devices that have no logic or storage function.

The function regions may correspond to design blocks placed in a design area, e.g., by using an APR tool. The near regions and far regions may be in white space between the design blocks. The near regions and far regions may be identified using a grid placed over the design area. The grid may include units arranged in rows and columns. The units may have a predetermined size, such as a predetermined height, predetermined width, etc. In an example, a minimum halo area that shares one or more units with a functional region may be identified as a near region of the functional region. A region that does not share any units with any functional region may be identified as a far region. The size of each unit may influence the size of the near region or far region. In some embodiments, the size of each unit may be determined based on the design blocks, e.g., types of the design blocks, components in the design blocks, shapes of the design blocks, sizes of the design blocks, and so on. For instance, the height or width of each unit may be equal to the height of an individual cell in a functional group. In some embodiments, the height or width of each unit may be in a range from approximately 100 nanometers to approximately 900 nanometers, e.g., in a range from approximately 200 nanometers to approximately 500 nanometers.

The present disclosure provides a white space fill method that is based on cloning the reference lines around active circuitry by a predetermined number of cell rows, which can push away the local layout effects from the immediate white space/design block boundary. Cloning information can be shared with upstream extraction flows in the Process Design Kit (PDK), thus giving designers predictability and visibility into what will abut to the cells that the designers have drawn. The white space fill method can enable a predetermined number of cell row protection against local layout effects and density fluctuations. Cloning the functional cells can allow an almost seamless transition between the design block and the white space. Design area can be saved by ensuring edge conditions. Additionally, a consistent boundary condition can be provided for both block level design rules and white space fill flow. The white space fill method can also design blocks design rule cleanliness independent of the context. Compared with currently available technologies, the white space fill methodology in the present disclosure can facilitate faster design closure and ease of use.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of field-effect transistors (FETs), designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

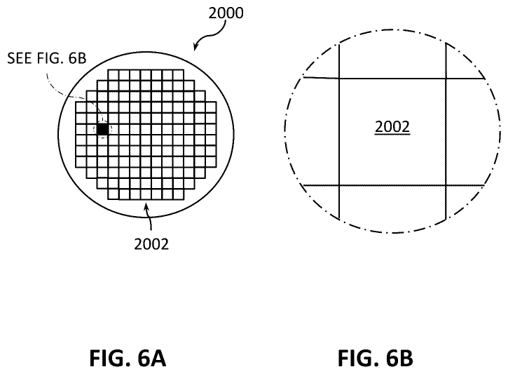

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 6A and 6B, such a collection may be referred to herein without the letters, e.g., as “FIG. 6.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of replica cells and filler cells as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various replica cells and filler cells as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

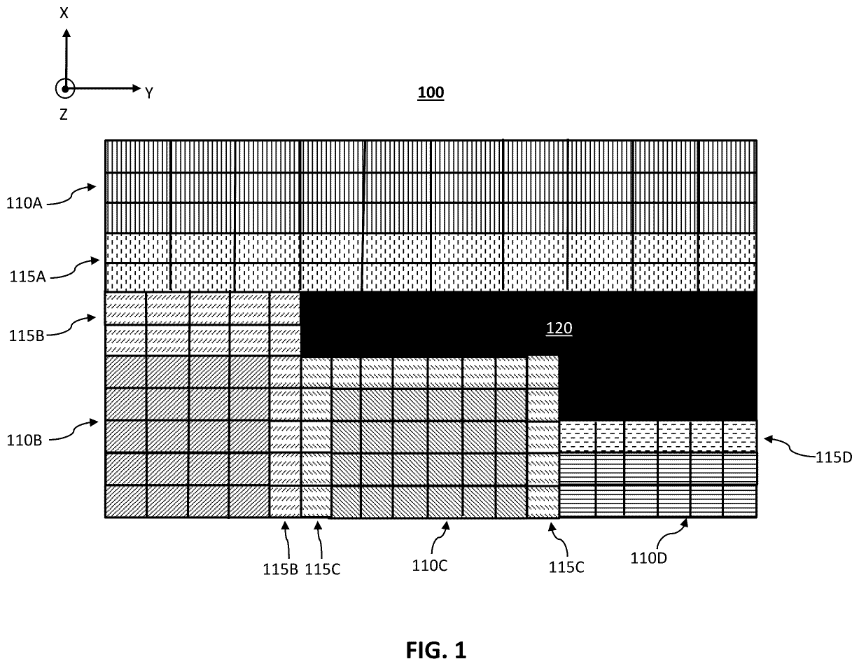

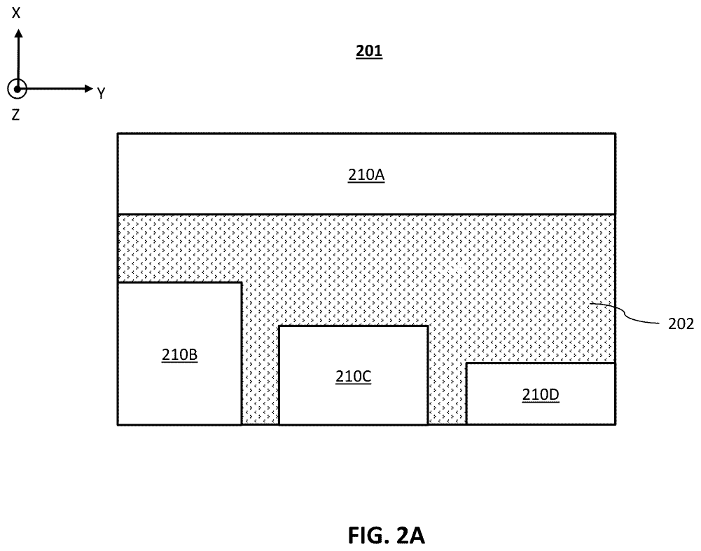

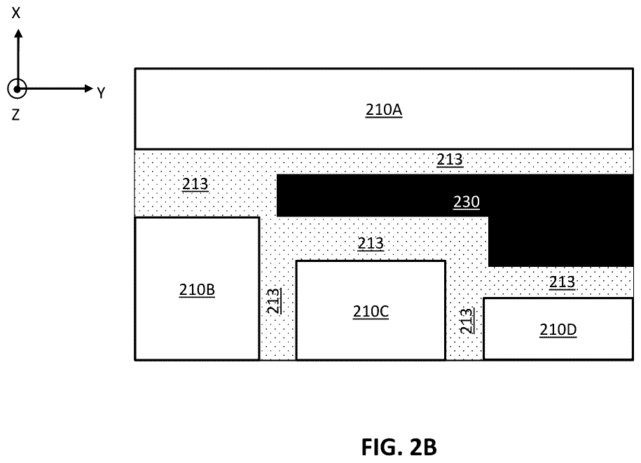

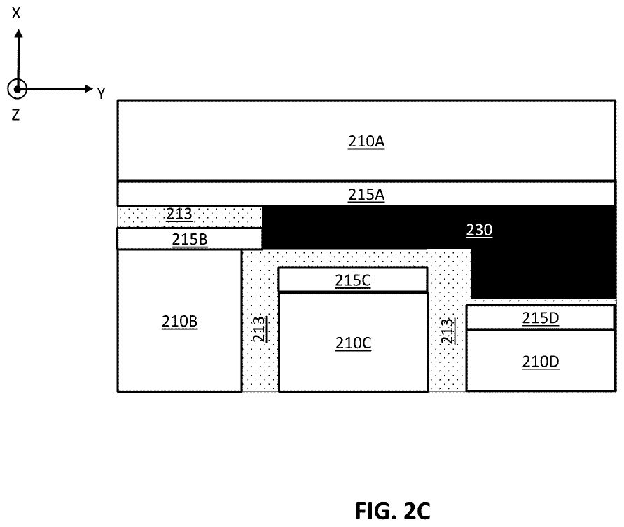

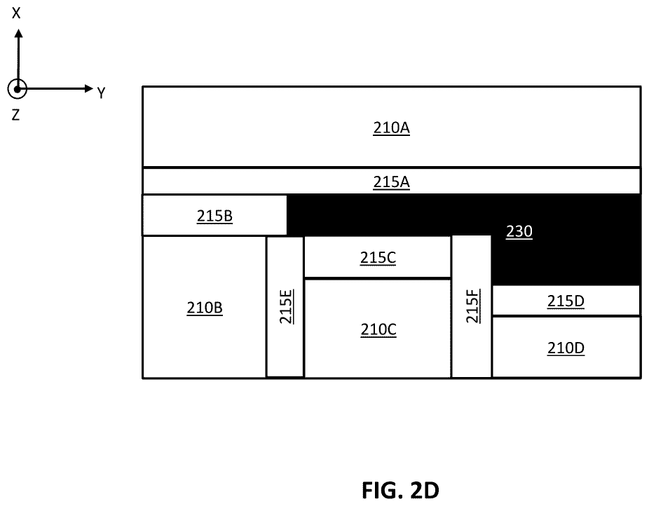

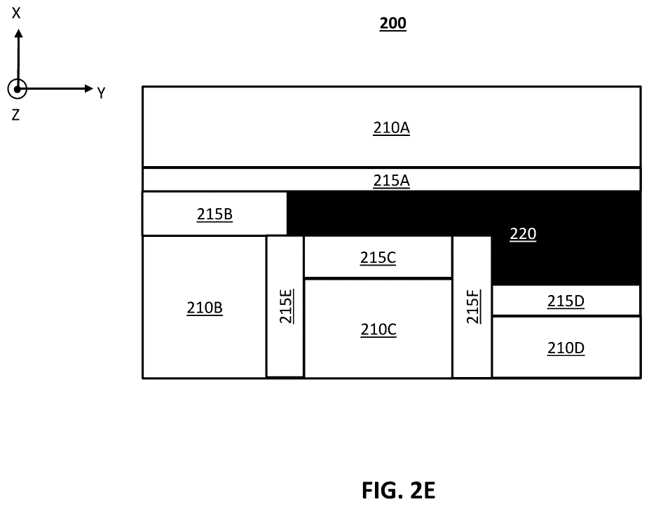

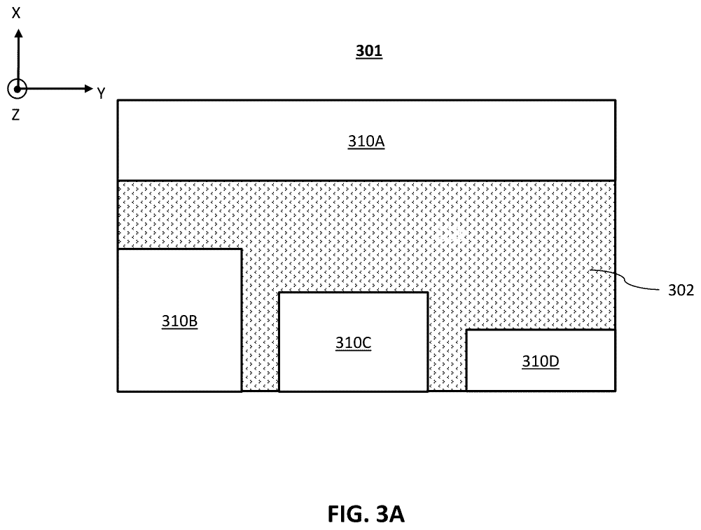

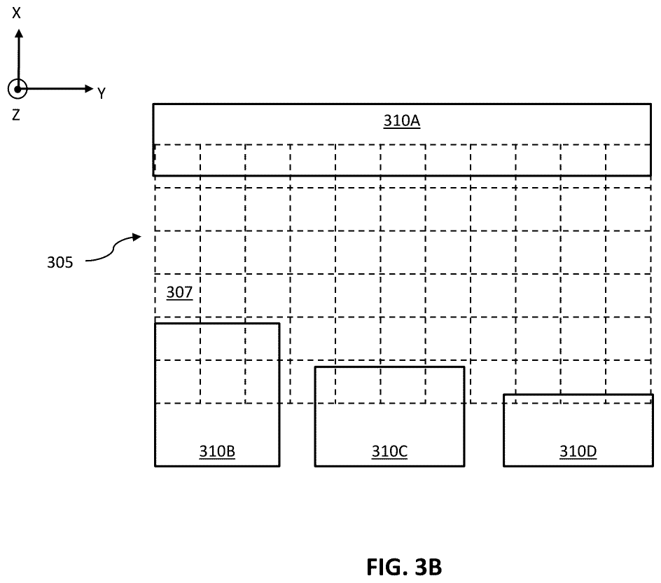

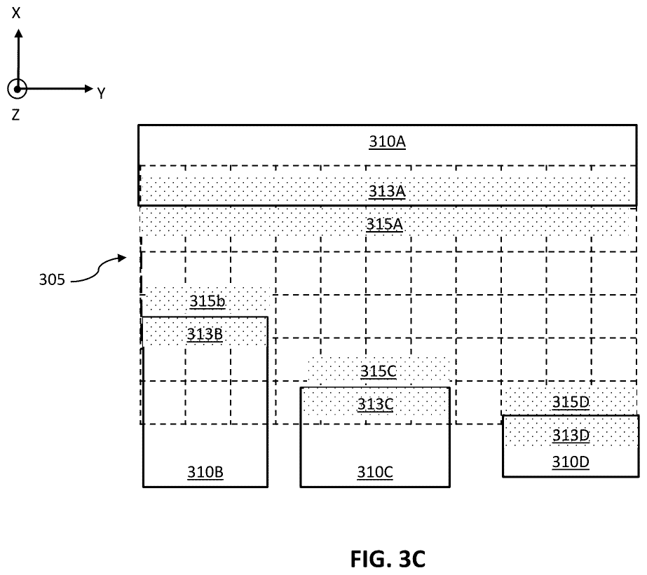

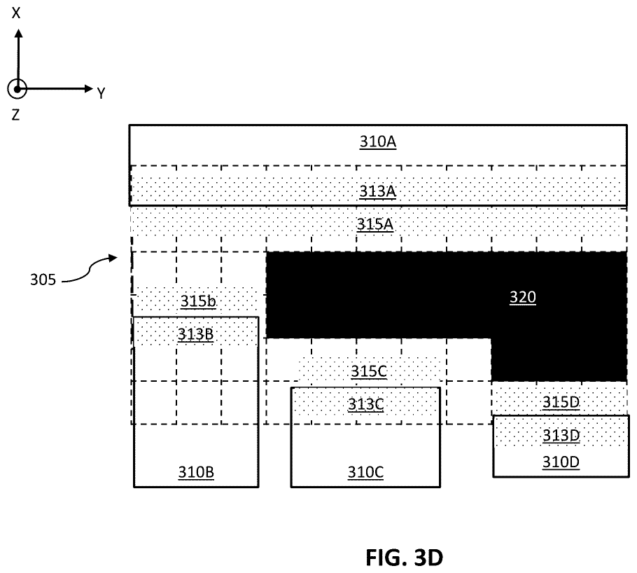

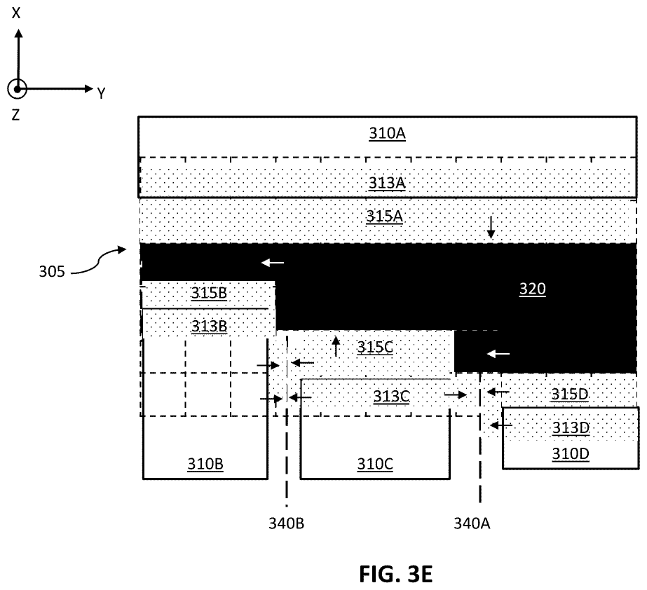

FIG. 1 illustrates an IC device 100 with replica cells and filler cells, according to some embodiments of the disclosure. The IC device 100 also includes functional cells, which constitute four separate functional regions 110A-110D (collectively referred to as “functional regions 110” or “functional region 110”). The replica cells constitute a number of replica regions 115A-115D (collectively referred to as “replica regions 115” or “replica region 115”). The filler cells constitute a non-functional region 120. In other embodiments, the IC device 100 may include fewer, more, or different components. For instance, the IC device 100 may include a different number of functional cells, replica cells, or filler cells. The IC device 100 may be formed by a process that includes design block integration and white space fill, such as the process illustrated in FIGS. 2A-2E or the process illustrated in FIGS. 3A-3E.

Each functional region 110 may be active in operations of the IC device 100. The functional regions 110 may have one or more logic functions, data storage functions, or some combination thereof. A functional region 110 may be, or may be a part of, a logic circuit or memory array. In some embodiments, the four functional regions 110 may have different logic or storage functions. In an example, a functional region 110 may be a memory array, while another functional region 110 may be a control circuit that can control operations of the memory array. Multiple functional regions 110 may have the same function in some embodiments. For instance, multiple functional regions 110 may each be a memory array.

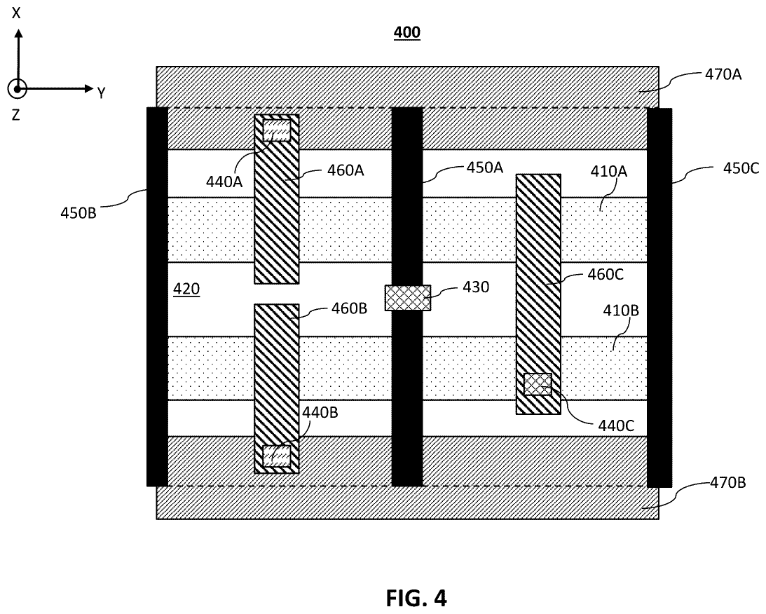

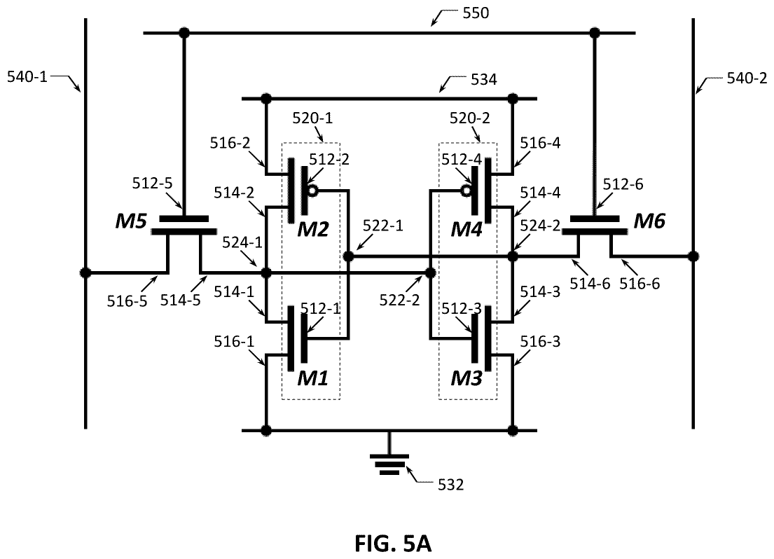

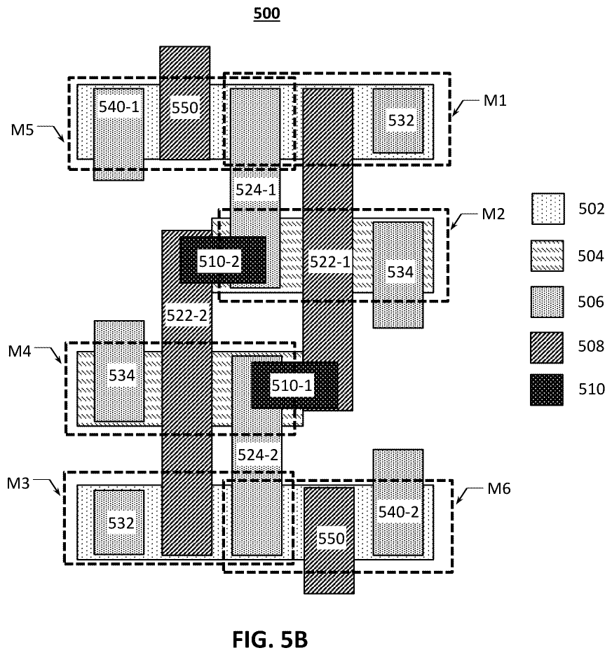

As shown in FIG. 1, each functional region 110 includes functional cells arranged in rows and columns. The functional region 110A includes three rows and 10 columns of functional cells. The functional region 110B includes five rows and four columns of functional cells. The functional region 110C includes four rows and six columns of functional cells. The functional region 110D includes two rows and six columns of functional cells. In other embodiments, the functional regions 110 may include different numbers of rows or columns. A functional cell is a unit component of the corresponding functional region 110. A functional cell may be a logic cell in a logic circuit or a memory cell in a memory array. Examples of the functional cells 110A-110D include the cell 400 in FIG. 4 and the cell 500 in FIGS. 5A and 5B.

The replica regions 115 are replicas of portions of the functional regions 110. In the embodiments of FIG. 1., a portion of the functional region 110A is cloned to form one replica region 115A, two portions of the functional region 110B are cloned to form two separate replica regions 115B (one replica region 115B is on top of the functional region 110B and the other replica region 115B is at the left side of the functional region 110B), three portions of the functional region 110C are cloned to form three separate replica regions 115C (one replica region 115C is on top of the functional region 110C, another replica region 115C is at the right side of the functional region 110C and yet another replica region 115C is at the left side of the functional region 110C), and a portion of the functional region 110D is cloned to form one replica region 115D. In other embodiments, a functional region 110 may be used to form a different number of replica regions.

Each replica region 115 abuts the functional region 110 based on which the replica region 115 is formed. A replica region 115 may abut another replica region 115. For instance, the replica region 115B at the left side of the functional region 110B also abuts the replica region 115C at the right side of the functional group 110C. The replica regions 115 also abut the non-functional region 120. As shown in FIG. 1, a replica region 115 may be between functional region 110 and the non-functional region 120. Replica cells may be unit components of the replica regions 115. A replica cell is a replication of a functional cell. The replica cell may include the same components and have the same function and size as the functional cell. In some embodiments, a functional cell or a replica cell may be a standard cell.

As shown in FIG. 1, a replica region may include one or more rows (or one or more columns) of replica cells. For instance, the replica region 115A includes two rows of replica cells. The replica region 115B on top of the functional region 110B includes two rows and four columns of replica cells. The replica region 115C on top of the functional region 110C and the replica region 115D each include one row of replica cells. The replica regions 115 may be formed by replicating the row(s) or column(s) of functional cells at the boundary of the corresponding functional region 110. For instance, the replica region 115A may be formed by replicating two rows of functional cells in the functional region 110A. The two rows of functional cells in the functional region 110A may be the two rows at the bottom of the functional region 110A, i.e., the two rows that are the closest to the boundary where the functional region 110A abuts the replica region 115A. Similarly, the replica region 115D may be formed by replicating the top row of functional cells in the functional region 110D, i.e., the row at the boundary where the functional region 110D abuts the replica region 115D.

Each replica region 115 may have a height along the X axis. Alternatively, the height of a replica region may be along the Y axis. The height of a replica region 115 may depend on the number of rows of replica cells in the replica region. For example, the height of the replica region 115A may be approximately twice the height of a functional cell in the functional region 110A, while the height of the replica region 115D may be approximately the height of a functional cell in the functional region 110D. In some embodiments, the height of a replica region 115 may be in a range from approximately 100 nanometers to approximately 900 nanometers, e.g., a range from approximately 200 nanometers to approximately 500 nanometers.

The non-functional region 120 may be inactive in operations of the IC device 100. Each filler cell in the non-functional region 120 does not implement any logic or storage functions. As shown in FIG. 1, the non-functional region 120 is between some of the replica regions 115. The non-functional region 120 is further from each functional region 110 than the replica region(s) 115 of the functional region 110. The non-functional region 120, together with the replica regions 115, can reduce local layout effects on the functional regions 110. Additionally, the non-functional region 120 may be used for one or more other purposes, such as voltage stability, power rail continuity, N-well continuity, P-well continuity, heat dissipation, isolation, and so on.

In some embodiments, the functional regions 110 may be formed based on design blocks in a design area that are provided by IC designers. A design block may specify the function of the design blocks, the number of cells in the design block, the type of cells in the design block, and so on. The replica regions 115 and the non-functional region 120 may be formed based on white space in the design area. The white space may be divided to near white space and far white space. The replica regions 115 may be formed based on the near white space, and the non-functional region 120 may be formed based on the far white space. More details regarding forming functional cells, replica cells, and filler cells are described below in conjunction with FIGS. 2A-2E and FIGS. 3A-3E.

The IC device 100 (e.g., the functional regions 110 in the IC device 100) may be manufactured by using one or more complementary metal-oxide-semiconductor (CMOS) processes, in which metal-oxide-semiconductor field-effect transistors (MOSFETs) (such as symmetrical pairs of P-type and N-type MOSFETs) can be fabricated. Also, metal layers may be implemented over the transistors. In some embodiments, the fabrication of the IC device 100 (or part of the IC device 100) may include two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. The FEOL stage may include a CMOS process, in which metal-oxide-semiconductor field-effect transistors (MOSFETs) (such as symmetrical pairs of P-type and N-type MOSFETs) can be fabricated. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

FIGS. 2A-2E illustrate a process of forming an IC device layout 200 including replica cells and filler cells, according to some embodiments of the disclosure. Although the process of forming the IC device layout 200 is described with reference to the steps illustrated in FIGS. 2A-2E, many other processes for forming IC device layouts may alternatively be used. For example, the order of execution of the steps illustrated in FIGS. 2A-2E may be changed. As another example, some of the steps may be changed, eliminated, or combined.

FIG. 2A shows a design area 201 that includes design blocks 210A-210D, collectively referred to as “design blocks 210” or “design block 210.” Each design block 210 may include a design of a functional region, such as one of the functional regions 110 in FIG. 1. A design block 210 may include information of an array of cells (e.g., standard cells). For instance, a design block 210 may specify the number of rows of cells, the number of columns of cells, components in each cell, size of each cell, electrical connections of one or more cells with one or more other cells or with one or more other design blocks 210, and so on. A cell may include a group of transistor and interconnect structures that can provide a logic function (e.g., AND, OR, XOR, XNOR, inverter, etc.) or a storage function (e.g., flipflop, latch, etc.). The design area 201 also includes white space 202. The white space 202 may be the portion of the design area 201 that is not taken by any design blocks 210. The white space 202 may be a gap area.

In FIG. 2B, near white blocks 213 (individually referred to as “near white block 213”) and a far white block 230 are identified in the white space 202. Each near white block 213 is a portion of the white space 202 that is adjacent to a design block 210. The near white block 213 may share a boundary with the corresponding design block 210. The far white block 230 is at least partially surrounded by the near white blocks 213. In some embodiments, an edge of the far white block 230 (e.g., the left edge of the far white block 230) may be aligned with a center of the near white block 213 between the design block 210B and the design block 210C. The center of the near white block 213 may be a center across the Y axis. In some embodiments, the classification of a portion of the white space 202 (i.e., whether the portion is classified as a near region or far region) may be determined based on attributes of the design block(s) under consideration. For instance, one or more dimensions of a near white block 213 may be determined based on electrical properties of the corresponding design block 210 (or one or more components in the design block 210). Examples of the electrical properties may include voltage, capacitance, current, and so on. In some embodiments, a height of a near white block 213 may correspond to the height of a cell in a design block 210. For instance, the height of a near white block 213 may be a predetermined number of times of the height of a cell in a design block 210. The near white block 213 may then be able to incorporate the predetermined number of rows of replica cells in the step shown in FIG. 2C.

In FIG. 2C, the near white blocks 213 can be at least partially filled with replica cells, forming replica blocks 215A-215D (collectively referred to as “replica blocks 215” or “replica block 215”). The replica cells may be formed by replicating cells in the design blocks 210. In the embodiments of FIG. 2C, each replica block 215 has a single row of replica cells. There are gaps left between replica blocks 215 or between a replica block 215 and the far white block 230.

In FIG. 2D, the gaps are filled by expanding some of the replica blocks 215. For instance, the replica block 215B is expanded to fill the gap between the replica block 215A and the original replica block 215B. Also, new replica blocks 215E and 215F are added to fill the gap between the design block 210B and 210C and the gap between the design block 210D and 210D. The expansion of the replica blocks 215A makes the far white block 230 smaller. As shown in FIG. 2D, each replica block 215 abuts at least one design block 210, one or more other replica blocks 215, or the far white block 230. A replica block 215 may be expanded by adding more replica cells into the replica block 215. These additional replica cells may be different from the original replica cells in the replica block 215. For example, these additional replica cells may be cloned from different cells in the corresponding design block 210 from the original replica cells.

In other embodiments, a replica block 215 may expand in a different way from what is shown in FIG. 2D. For instance, the replica block 215A may be expanded to fill the gap between the design block 210A and the design block 210B without making the far white block 230 smaller. Additionally or alternatively, the far white block 230 may be expanded to fill one or more of the gaps shown in FIG. 2C. For instance, the far white block 230, in lieu of the replica block 215A or the replica block 215B, may expand to fill the gap between the design block 210A and the design block 210B. Embodiments of the replica blocks 215 include the replica regions 115 in FIG. 1.

In FIG. 2E, the far white block 230 is provided with filler cells to form a non-functional block 220. The IC device layout 200 is formed. The IC device layout 200 may be used to fabricate IC devices, e.g., the IC device 100 in FIG. 1. The shapes, sizes, or locations of the design blocks 210, near white blocks 213, far white block 230, replica blocks 215, and non-functional block 220 in FIGS. 2A-2E are used for illustration. In other embodiments, the design blocks 210, near white blocks 213, far white block 230, replica blocks 215, or non-functional block 220 may have different shapes, sizes, or locations.

FIGS. 3A-3E illustrate another process of forming an IC device layout 300 including replica cells and filler cells, according to some embodiments of the disclosure. Although the process of forming the IC device layout 300 is described with reference to the steps illustrated in FIGS. 3A-3E, many other processes for forming IC device layouts may alternatively be used. For example, the order of execution of the steps illustrated in FIGS. 3A-3E may be changed. As another example, some of the steps may be changed, eliminated, or combined.

FIG. 3A shows a design area 301 that includes design blocks 310A-210D, collectively referred to as “design blocks 310” or “design block 310.” Each design block 310 may include a design of a functional region, such as one of the functional regions 110 in FIG. 1. A design block 310 may include information of an array of cells (e.g., standard cells). For instance, a design block 310 may specify the number of rows of cells, the number of columns of cells, components in each cell, size of each cell, electrical connections of one or more cells with one or more other cells or with one or more other design blocks 310, and so on. A cell may include a group of transistor and interconnect structures that can provide a logic function (e.g., AND, OR, XOR, XNOR, inverter, etc.) or a storage function (e.g., flipflop, latch, etc.). The design area 301 also includes white space 302. The white space 302 may be the portion of the design area 301 that is not taken by any design blocks 310. The white space 302 may be a gap area.

In FIG. 3B, a grid 305 is placed in the design area 301. The grid 305 includes elements 307 (individually referred to as “element 307”) arranged in six rows and 11 columns. Each element 307 may have a predetermined dimension along the X or Y axis. In an example, the predetermined dimension of each element 307 may be the height of a cell in a design block 310. In another example, the predetermined dimension of each element 307 may be in a range from approximately 100 nanometers to approximately 900 nanometers. In some embodiments, the sizes of the elements 307 may be the same. The grid 305 may be placed in a way that a center of the grid 305 overlaps or is aligned with a center of the design area 301. The grid 305 may include a different number of rows or columns in other embodiments. One or more additional rows or columns may be added to the grid 305. Similarly, one or more rows or columns may be removed from the grid 305. Even though the grid 305 does not cover the entire design area 301 in FIG. 3A, the grid 305 may fill the entire design area 301 in other embodiments. For the purpose of simplicity, the white space 302 is not shown in FIGS. 3B-3E.

In FIG. 3C, replica blocks 315A-315D are identified based on the grid 305 (collectively referred to as “replica blocks 315” or “replica block 315”). In an example, a replica block 315 is placed in some elements 307 of the grid 305. Each of these elements 307 is partially taken by a portion of a design block 310. These elements 307 may be determined as having significant local layout effects that should be reduced. In the embodiments of FIG. 3B, cell rows 313A-313D (collectively referred to as “cell rows 313” or “cell row 313”) are identified in the design blocks 310A-310D, respectively. Each cell row 313 may be a row of functional cells in the corresponding design block 310. A cell row 313 may be the row at the boundary of the design block 310 that faces one or more other design blocks 310. The cell rows 313A-313D are cloned to produce replica blocks 315A-315D collectively referred to as “replica blocks 315” or “replica block 315”), respectively. Each replica block 315 may include a single row of replica cells. The replica blocks 315 are outside the design blocks 310 and are located in the white space 302. In other embodiments, multiple cell rows may be cloned to produce multiple cell rows for one or more design blocks 310.

In FIG. 3D, a non-functional block 320 is formed in a portion of the white area 302. The portion of the white area 302 may be determined by identifying elements 307 of the grid 305 that are not over any of the design blocks 310 or replica blocks 315. Filler cells may be provided to the identified elements 307 of the grid 305 to form the non-functional block 320. After the replica blocks 315 and non-functional block 320 are formed, there are still gaps in the white area 302. These gaps are not taken by any design blocks 310, replica blocks 315, or the non-functional block 320.

In FIG. 3E, some or all of the gaps are filled. FIG. 3E shows various arrows that indicate expansion of some replica blocks 315 (e.g., by adding another cell row) and expansion of the non-functional block 320 (e.g., by adding more filler cells). Also, new replica cells are formed in the gap between the design block 310B and the design block 310C. An intermediate boundary 340A is identified. Some cells in the design block 310B are cloned and provided to the gap between the design block 310B and the intermediate boundary 340A. Some cells in the design block 310C are cloned and provided to the gap between the design block 310C and the intermediate boundary 340A. Similarly, an intermediate boundary 340B is identified between the design block 310C and the design block 310D. Some cells in the design block 310C are cloned and provided to the gap between the design block 310C and the intermediate boundary 340B. Some cells in the design block 310D are cloned and provided to the gap between the design block 310D and the intermediate boundary 340B.

The IC device layout 300 is formed. The IC device layout 300 may be used to fabricate IC devices, e.g., the IC device 100 in FIG. 1. The shapes, sizes, or locations of the design blocks 310, replica blocks 315, and non-functional block 320 in FIGS. 3A-3E are used for illustration. In other embodiments, the design blocks 310, replica blocks 315, or non-functional block 320 may have different shapes, sizes, or locations.

FIG. 4 illustrates an example cell 400, according to some embodiments of the disclosure. The cell 400 may be a standard cell. The cell 400 may have a logic function or a storage function. In some embodiments, the cell 400 may be a logic cell, a memory cell, etc. The boundaries of the cell 400 are represented by dashed lines in FIG. 4. The cell 400 includes semiconductor structures 410A and 410B (collectively referred to as “semiconductor structures 410” or “semiconductor structure 410”), an electrical insulator 420, via 430, vias 440A-440C (collectively referred to as “vias 440” or “via 440”), gate electrodes 450A-450C (collectively referred to as “gate electrodes 450” or “gate electrode 450”), electrodes 460A-460C (collectively referred to as “electrodes 460” or “electrode 460”), and metal tracks 470A and 470B (collectively referred to as “metal tracks 470” or “metal track 470”). The metal tracks 470 may be in a metal layer in the cell 400. In other embodiments, the cell 400 may include different, fewer, or more components. For example, the cell 400 may include a different number of semiconductor structures 410, gate electrodes 450, or electrodes 460. As another example, the cell 400 may include one or more other metal layers.

FIG. 4 shows an X axis, a Y axis, and a Z axis. The X axis may be the vertical axis of the cell 400. The dimension of the cell 400 along the X axis (e.g., the distance between the two opposing boundaries of the cell 400 along the Y axis) may be the height of the cell 400. The dimension of the cell 400 along the Y axis (e.g., the distance between the two opposing boundaries of the cell 400 along the X axis) may be the width of the cell 400. The distance between two adjacent gate electrodes 450 (e.g., the distance between the gate electrodes 450A and 450B or the distance between the gate electrodes 450A and 450C) may be the contacted poly pitch of the cell 400. In some embodiments, the metal layer may be arranged over the semiconductor structures 410, an electrical insulator 420, via 430, vias 440, gate electrodes 450, and electrodes 460 in a direction along the Z axis.

A semiconductor structure 410 may include one or more semiconductor materials. In some embodiments, a semiconductor structure 410 may be a semiconductor substrate based on which transistors can be formed. In some embodiments, the semiconductor structures 410 may include semiconductors with opposite doping types. For instance, the semiconductor structure 410A may be a N-type semiconductor structure, while the semiconductor structure 410B may be a P-type semiconductor structure. In other embodiments, the semiconductor structures 410 may include semiconductors with the same doping type. In some embodiments, a semiconductor structure 410 may have a planar structure. In other embodiments, a semiconductor structure 410 may have a non-planar structure, such as fin, nanoribbon, and so on.

A semiconductor structure 410 may have a longitudinal axis. In some embodiments, a dimension of the semiconductor structure 410 along its longitudinal axis may be greater than the dimension of the semiconductor structure 410 in a direction perpendicular to the longitudinal axis. For instance, the semiconductor structure 410 may have a longitudinal axis parallel to the Y axis. The dimension of the semiconductor structure 410 along the Y axis may be greater than the dimension of the semiconductor structure 410 along the X axis or the Z axis. The semiconductor structure 410 may also have a transverse cross-section, which may be a cross-section in a plane perpendicular to the its longitudinal axis.

A semiconductor structure 410 may include a source region, channel region, and drain region of a transistor. The channel region may be between the source region and drain region in a direction along the Y axis. The channel region may be over a portion of the gate electrode 450A. The source region may be over a portion of an electrode 460. The drain region may be over a portion of another electrode 460. For instance, a portion of the semiconductor structure 410A under the electrode 460A may be one of the source region and drain region of a transistor, a portion of the semiconductor structure 410A under the gate electrode 450A may be the channel region of the transistor, and a portion of the semiconductor structure 410A under the electrode 460C may be the other one of the source region and drain region of the transistor. Similarly, a portion of the semiconductor structure 410B under the electrode 460B may be one of the source region and drain region of a transistor, a portion of the semiconductor structure 410B under the gate electrode 450A may be the channel region of the transistor, and a portion of the semiconductor structure 410B under the electrode 460C may be the other one of the source region and drain region of the transistor. The two transistors may be FETs. In an embodiment, the two transistors are both P-type transistors, e.g., P-type metal-oxide-semiconductor (PMOS) transistors. In another embodiment, the two transistors are both N-type transistors, e.g., N-type metal-oxide-semiconductor (NMOS) transistors. In yet another embodiment, one of the two transistors is an N-type transistors, while the other one is a P-type transistors.

A channel region of a transistor may include a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example N-type transistor embodiments (i.e., for the embodiments where a transistor is an NMOS transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material may be relatively low, for example below 10¹⁵ dopant atoms per cubic centimeter (cm⁻³), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where a transistor is a PMOS transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, n-or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front-end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO3 (ZnO) 5. Another example form of IGZO has an indium: gallium: zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The source region and drain region in a transistor are connected to the channel region. The source region and drain region may each include a semiconductor material with dopants. In some embodiments, the source region and drain region have the same semiconductor material, which may be the same as the channel material of the channel region. A semiconductor material of the source region or the drain region may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region are the same type. In other embodiments, the dopants of the source region and the drain region may be different (e.g., opposite) types. In an example, the source region has N-type dopants and the drain region has P-type dopants. In another example, the source region has P-type dopants and the drain region has N-type dopants. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region and the drain region may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region may be the regions having dopant concentration higher than in other regions, e.g., higher than a dopant concentration in the channel region, and, therefore, may be referred to as “highly doped” (HD) regions.

The channel region may include one or more semiconductor materials with doping concentrations significantly smaller than those of the source region and the drain region. For example, in some embodiments, the channel material of the channel region may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region and the drain region, for example below 10¹⁵ cm⁻³ or below 10¹³ cm⁻³. Depending on the context, the term “S/D terminal” may refer to a S/D region or a S/D contact or electrode of a transistor.

A gate electrode 450 includes one or more conductive materials, such as metal, polycrystalline silicon, other types of conductive materials, or some combination thereof. In some embodiments, the choice of the conductive materials in the gate electrode 450 (e.g., the gate electrode 450A) may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, a gate electrode 450 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. In some embodiments, the gate electrode 450B or 450C may be a dummy gate electrode. The gate electrode 450B or 450C may not be coupled to any power plane, ground plane, or signal plane.

Each electrode 460 may be over a source region or drain region of a transistor in the cell 400. An electrode 460 over a source region may be referred to as a source electrode. An electrode 460 over a drain region may be referred to as a drain electrode. An electrode 460 may include one or more electrically conductive materials. An electrically conductive material may be metal. Examples of metals in an electrode 460 may include, but are not limited to, Ru, Cu, Co, palladium, platinum, nickel, and so on. In the embodiments of FIG. 4, the electrode 460A is separated from the electrode 460B by the electrical insulator 420. The electrode 460A and the electrode 460B may be at different electrical potentials during the operation of the cell 400. The electrode 460C may constitute the trench electrodes of two transistors, the source or drain region of which may be subject to the same electrical potential. In other embodiments, the cell 400 may include a single electrode in lieu of the electrodes 460A and 460B. Also, the cell 400 may include two separate electrodes in lieu of the electrode 460C. Even though not shown in FIG. 4, a gate electrode 450 or an electrode 460 may be separated from the electrical insulator 420 by a dielectric material. In some embodiments, the gate electrode 450 or electrode 460 may be partially or wholly wrapped by the dielectric material.

The electrical insulator 420 may separate and insulate semiconductor components or conductive components in the cell 400. In some embodiments, the electrical insulator 420 may wholly or partially wrap one or more other components of the cell 400. For instance, the electrical insulator 420 may wholly or partially wrap the via 430 or 440, a semiconductor structure 410, gate electrode 450, electrode 460, etc. The electrical insulator 420 may include one or more electrical insulative materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, and so on.

The vias 430 and 440 are electrically conductive. Each of the vias 430 and 440 may include one or more electrical conductors, such as metal, and so on. In some embodiments, each of the vias 430 and 440 may have a longitudinal axis, which may be parallel to the Z axis. In some embodiments, a dimension of each of the vias 430 and 440 along its longitudinal axis may be greater than the dimension of the via in a direction perpendicular to the longitudinal axis, e.g., in a direction along the X axis or the Y axis. Each of the vias 430 and 440 may have a transverse cross-section, which may be a cross-section in a plane (e.g., an X-Y plane) perpendicular to its longitudinal axis.

As shown in FIG. 4, the via 430 is connected to the gate electrode 450A, and the vias 440 are each connected to an electrode 460. In some embodiments, the via 430 may be an input pin of the cell 400 and can support the cell 400 to receive signals from one or more other devices. A via 440 may be an output pin of the cell 400 and can support the cell 400 to transmit signals to one or more other devices. The via 430 may couple the gate electrode 450A to another structure, e.g., a metal track of a metal layer (e.g., M0) arranged over the cell 400 in a direction along the Z axis. Each via 440 may couple the corresponding electrode 460 to another structure, e.g., a metal track of a metal layer (e.g., M0) arranged over the cell 400 in a direction along the Z axis.

In some embodiments, the via 440A may have an end connected to the electrode 460A and another end connected to the metal track 470A. The via 440B may have an end connected to the electrode 460B and another end connected to the metal track 470B. A metal track 470 may also be referred to as a metal line, metal interconnect, or metal structure. In some embodiments, the metal tracks 470 have longitudinal axes that are parallel or substantially parallel to each other. The metal tracks 470 may facilitate power delivery to the cell 400. In some embodiments, the metal tracks 470 may be separated from each other by one or more electrical insulators. The metal tracks 470 may be a power plane and a ground plane, respectively, which can deliver power to the cell 400. In some embodiments, the metal layer including the metal tracks 470 may be M0 in the BEOL section. The cell 400 may include one or more other metal layers stacked over the metal layer in a direction along the Z axis.

FIGS. 5A and 5B illustrate another example cell 500, according to some embodiments of the disclosure. The cell 500 may be a functional cell, e.g., a memory cell. In some embodiments, the cell 500 is a static random-access memory (SRAM) cell. FIG. 5A shows an electric circuit diagram of the cell 500. FIG. 5B provides a top-down plan view of an example implementation of the cell 500.

The cell 500 includes transistors M1-M4 for storing a bit value or a memory state (e.g., logic “1” or “0”) of the cell, and two access transistors, M5 and M6, for controlling access to the cell (e.g., access to write information to the cell or access to read information from the cell 500). The cell 500 is a 6-transistor (6T) memory cell. In other embodiments, the cell 500 may include a different number of transistors. Each of the transistors M1-M6 may have any transistor architecture, such as planar or non-planar (e.g., FinFET, nanoribbon/nanowire, etc.).

In the cell 500, each bit may be stored on four transistors (M1, M2, M3, M4) that form two cross-coupled inverters 520, each having an input 522 and an output 524. The first inverter 520-1 may be formed by an NMOS transistor M1 and a PMOS transistor M2, while the second inverter 520-2 may be formed by an NMOS transistor M3 and a PMOS transistor M4. The gate stack 512-1 of the transistor M1 may be coupled to the gate stack 512-2 of the transistor M2. Both of these gate stacks may be coupled to the input 522-1 of the first inverter 520-1. The first S/D region 514-1 of the transistor M1 may be coupled to the first S/D region 514-2 of the transistor M2. Both of these first S/D regions 514-1 and 514-2 may be coupled to the output 524-1 of the first inverter 520-1.

For the second inverter 520-2, the gate stack 512-3 of the transistor M3 may be coupled to the gate stack 512-4 of the transistor M4, and both of these gate stacks may be coupled to the input 522-2 of the second inverter 520-2. The first S/D region 514-3 of the transistor M3 may be coupled to the first S/D region 514-4 of the transistor M4, and both of these first S/D regions 514-3 and 514-4 may be coupled to the output 524-2 of the second inverter 520-2. When the transistors M1 and M3 are NMOS transistors and when the transistors M2 and M4 are PMOS transistors, the second S/D regions 516-1 and 516-3 of the transistors M1 and M3 may be coupled to a ground voltage 532, while the second S/D regions 516-2 and 516-4 of the transistors M2 and M4 may be coupled to a supply voltage 534, e.g., VDD. In the embodiments of the cell 500 where the NMOS transistors are replaced with PMOS transistors and vice versa, the designation of the ground voltage 532 and the supply voltage 534 would be reversed as well, all of which embodiments being within the scope of the present disclosure.

The four transistors M1-M4 in such configuration form a stable storage cell for storing a bit value of 0 or 1. Two additional access transistors, M5 and M6, may serve to control the access to the storage cell of the transistors M1-M4 during read and write operations. The first S/D region 514-5 of the access transistor M5 may be coupled to the output 524-1 of the first inverter 520-1. Phrased differently, the first S/D region 514-5 of the access transistor M5 may be coupled to each of the first S/D region 514-1 of the transistor M1 and the first S/D region 514-2 of the transistor M2. The second S/D region 516-5 of the access transistor M5 may be coupled to a first bit line 540-1. Thus, each of the first S/D region 514-1 of the transistor M1 and the first S/D region 514-2 of the transistor M2 may be coupled to the first bit line 540-1 (e.g., via the access transistor M5). The gate 512-5 of the access transistor M5 may be coupled to a word line 550.

The first S/D region 514-6 of the access transistor M6 may be coupled to the output 524-2 of the second inverter 520-2. Phrased differently, the first S/D region 514-6 of the access transistor M6 may be coupled to each of the first S/D region 514-3 of the transistor M3 and the first S/D region 514-4 of the transistor M4. The second S/D region 516-6 of the access transistor M6 may be coupled to a second bit line 540-2. Thus, each of the first S/D region 514-3 of the transistor M3 and the first S/D region 514-4 of the transistor M4 may be coupled to the second bit line 540-2 (e.g., via the access transistor M6). The gate 512-6 of the access transistor M6 may be coupled to the word line 550. Thus, the gates 512-5 and 512-6 of both of the access transistors M5 and M6 may be coupled to a single, shared, word line, the word line 550.

The input 522-1 of the first inverter 520-1 may be coupled to the first S/D region 514-6 of the access transistor M6, while the input 522-2 of the second inverter 520-2 may be coupled to the first S/D region 514-5 of the access transistor M5. In other words, each of the gate stack 512-1 of the transistor M1 and the gate stack 512-2 of the transistor M2 may be coupled to the first S/D region 514-6 of the access transistor M6, while each of the gate stack 512-3 of the transistor M3 and the gate stack 512-4 of the transistor M4 may be coupled to the first S/D region 514-5 of the access transistor M5. Phrased differently, each of the gate stack 512-1 of the transistor M1 and the gate stack 512-2 of the transistor M2 may be coupled to the second bit line 540-2 (e.g., via the access transistor M6), while each of the gate stack 512-3 of the transistor M3 and the gate stack 512-4 of the transistor M4 may be coupled to the first bit line 540-1 (e.g., via the access transistor M5).

The word line 550 and the first and second bit lines 540 may be used together to read and program (i.e., write to) the cell 500. In particular, access to the cell may be enabled by the word line 550 which controls the two access transistors M5 and M6 which, in turn, control whether the cell 500 should be connected to the bit lines 540-1 and 540-2. During operation of the cell 500, a signal on the first bit line 540-1 may be complementary to a signal on the second bit line 540-2. The two bit lines 540 may be used to transfer data for both read and write operations. In other embodiments of the cell 500, only a single bit line 540 may be used, instead of two bitlines 540-1 and 540-2, although having one signal bit line and one inverse, such as the two bit lines 540, may help improve noise margins.

During read accesses, the bit lines 540 may be actively driven high and low by the inverters 520 in the cell 500. The symmetric structure of the cell 500 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the word line 550 and the bit lines 540, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 5B illustrates how the six transistors M1-M6 shown in FIG. 5A may be implemented. Several elements from FIG. 5A are labelled in FIG. 5B. For example, the transistors M1-M6 are labelled in FIG. 5B, with the approximate boundaries of the individual transistors shown in FIG. 5B with dashed rectangles. Certain elements, e.g., the specific S/D regions 514 and 516 and the gate stacks 512, are not labelled in FIG. 5B in order to not clutter the drawings.

Transistors M1 and M5 may be provided along a first region of an N-type semiconductor 502, transistors M2 and M4 may each be provided along a respective first and second region of a P-type semiconductor 504, and the transistors M4 and M6 may be provided along a second region of the N-type semiconductor 502. Each of the regions of the N-type semiconductor 502 and P-type semiconductor 504 may be formed in a support structure (e.g., a substrate) or over a support structure, e.g., as a fin or nanoribbon. The N-type semiconductor 502 is suitable for forming transistors of a first type, e.g., NMOS transistors, while the P-type semiconductor 504 is suitable for forming transistors of a second type, e.g., PMOS transistors, thus realizing NMOS transistors M1, M3, M5, and M6, and PMOS transistors M2 and M4.

S/D contacts 506, gate electrodes 508, and interconnects 510 are formed over the N-type and P-type semiconductors 502 and 504, e.g., as layers processed over the N-type and P-type semiconductors 502 and 504. While not specifically shown in FIG. 5B, S/D regions may be formed under the S/D contacts 506, and gate dielectrics may be formed under the gate electrodes 508. Any of the materials and processes described with respect to FIG. 4 may be used to form the transistors shown in FIG. 5B.

More specifically, a shared gate stack may be used to realize the gate stack 512-1 of the transistor M1 coupled to the gate stack 512-2 of the transistor M2. The shared gate stack is labelled 522-1 in FIG. 5B, representing a node that is the input 522-1 of the first inverter 520-1 of the cell 500. Similarly, a shared gate stack may be used to realize the gate stack 212-3 of the transistor M3 coupled to the gate stack 212-4 of the transistor M4 3. The shared gate stack is labelled 522-2 in FIG. 5B, representing a node that is the input 522-2 of the second inverter 520-2 of the cell 500.

A first shared S/D contact may be used to realize the first S/D region 514-1 of the transistor M1 coupled to the first S/D region 514-2 of the transistor M2. The first shared S/D contact is labelled 524-1 in FIG. 5B, representing a node that is the output 524-1 of the first inverter 520-1 of the cell 500. Similarly, a second shared S/D contact may be used to realize the first S/D region 514-3 of the transistor M3 coupled to the first S/D region 514-4 of the transistor M4. The first shared S/D contact is labelled 524-2 in FIG. 5B, representing a node that is the output 524-2 of the second inverter 520-2 of the cell 500.

A first interconnect 510-1 may then be used to couple the shared gate stack 522-1 of the first inverter 520-1 to the shared S/D contact 524-2 of the second inverter 520-2, thus realizing the coupling of the input 522-1 of the first inverter 520-1 to the output 524-2 of the second inverter 520-2. Similarly, a second interconnect 510-2 may then be used to couple the shared gate stack 522-2 of the second inverter 520-2 to the shared interconnect 524-1 of the first inverter 520-1, thus realizing the coupling of the input 522-2 of the second inverter 520-2 to the output 524-1 of the first inverter 520-1.

In a given cell 500, the first S/D region 514-5 of the transistor M5 may be shared with (e.g., be the same as) the first S/D region 514-1 of the transistor M1 (since both of these transistors are implemented in a single region of the N-type semiconductor 502). In addition, the first S/D region 514-3 of the transistor M3 may be shared with (e.g., be the same as) the first S/D region 514-6 of the transistor M6 (since both of these transistors are implemented in a single region of the N-type semiconductor 502).

Both of the second S/D region 516-1 of the transistor M1 and the second S/D region 516-3 of the transistor M3 may be coupled to the ground voltage 532, as was described with reference to FIG. 5B. Both of the second S/D region 516-2 of the transistor M2 and the second S/D region 516-4 of the transistor M4 may be coupled to the supply voltage 534.

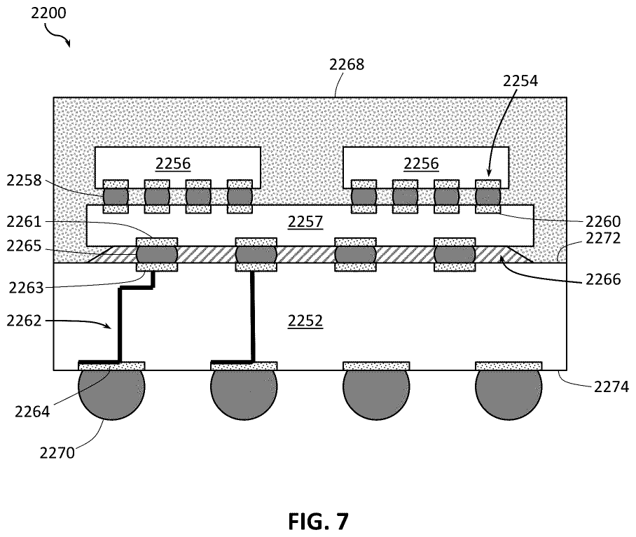

FIGS. 6A and 6B are top views of a wafer 2000 and dies 2002 that may include one or more IC devices with replica cells and filler cells, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 7. The wafer 2000 may be composed of semiconductor material and may include one or more dies 2002 having IC devices formed on a surface of the wafer 2000. An IC device may include one or more replica cells and filler cells. Examples of the IC device may include the IC device 100 in FIG. 1. Each of the dies 2002 may be a repeating unit of a semiconductor product that includes any suitable IC (e.g., ICs with replica cells and filler cells as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include replica cells and filler cells as disclosed herein may take or include components that take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 7 is a side, cross-sectional view of an example IC package 2200 that may include one or more IC devices with replica cells and filler cells, according to some embodiments of the disclosure. In some embodiments, the IC package 2200 may be a system-in-package (SiP).

As shown in FIG. 7, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 7 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 7 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

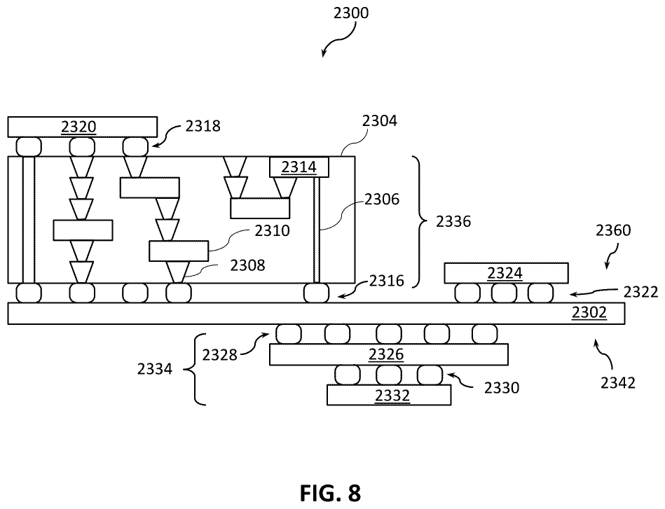

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 7 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 8.

The dies 2256 may take the form of any of the embodiments of the die 2002 discussed herein and may include any of the embodiments of an IC device with replica cells and filler cells. In embodiments in which the IC package 2200 includes multiple dies 2256, the IC package 2200 may be referred to as a multi-chip package. Importantly, even in such embodiments of an MCP implementation of the IC package 2200, one or more IC devices with replica cells and filler cells may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc. In some embodiments, any of the dies 2256 may include one or more backside metal layers. In some embodiments, at least some of the dies 2256 may not include any III-N diodes with n-doped wells and capping layers.

The IC package 2200 illustrated in FIG. 7 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 7, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 8 is a cross-sectional side view of an IC device assembly 2300 that may include components having one or more IC devices with replica cells and filler cells, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices with replica cells and filler cells in accordance with any of the embodiments disclosed herein; e.g., any of the IC packages discussed below with reference to the IC device assembly 2300 may take the form of any of the embodiments of the IC package 2200 discussed above with reference to FIG. 7 (e.g., may include replica cells and filler cells in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 7), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 6B), an IC device (e.g., the IC device 100 of FIG. 1), or any other suitable component. In particular, the IC package 2320 may include one or more IC devices with replica cells and filler cells as described herein. Although a single IC package 2320 is shown in FIG. 8, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 8, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices with replica cells and filler cells as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

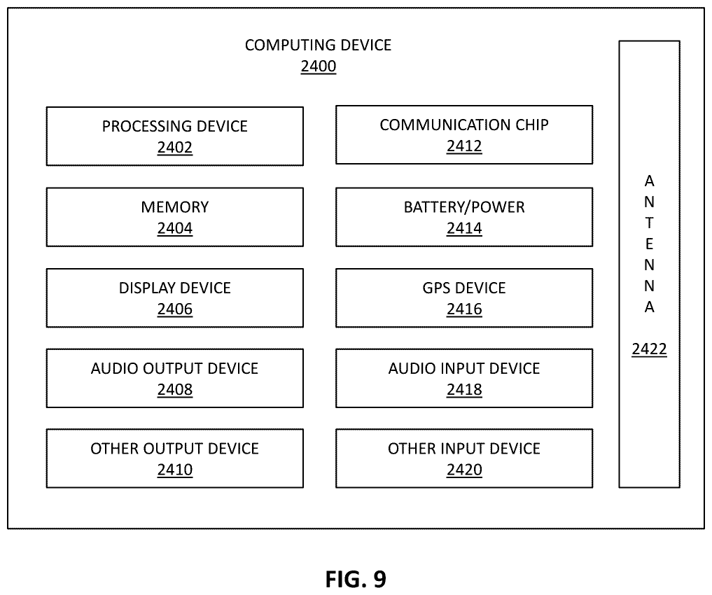

FIG. 9 is a block diagram of an example computing device 2400 that may include one or more components with one or more IC devices with replica cells and filler cells, according to some embodiments of the disclosure. For example, any suitable ones of the components of the computing device 2400 may include a die (e.g., the die 2002 of FIG. 6B) including replica cells and filler cells, according to some embodiments of the disclosure. Any of the components of the computing device 2400 may include an IC device (e.g., the IC device 100 in FIG. 1) and/or an IC package (e.g., the IC package 2200 of FIG. 7). Any of the components of the computing device 2400 may include an IC device assembly (e.g., the IC device assembly 2300 of FIG. 8).

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a first functional region including first semiconductor devices, a first semiconductor device having a first logic or storage function; a second functional region including second semiconductor devices, a second semiconductor device having a second logic or storage function; a replica region including one or more first semiconductor devices of the first functional region; and a non-functional region, in which the replica region and the non-functional region are between the first functional region and the second functional region, the first functional region is closer to the replica region than to the non-functional region.

Example 2 provides the IC device according to example 1, in which the first semiconductor devices are in standard cells.

Example 3 provides the IC device according to example 2, in which a height of the replica region is the same or substantially similar as a height of a standard cell.

Example 4 provides the IC device according to example 3, in which the standard cell includes conductive structures stacked in a first direction, and the height of the standard cell is a dimension of the standard cell in a second direction that is perpendicular to the first direction.

Example 5 provides the IC device according to any one of examples 1-4, in which: the replica region is a first replica region, the IC device further includes a second replica region that includes one or more second semiconductor devices of the second functional region, and the second functional region is closer to the second replica region than to the non-functional region.

Example 6 provides the IC device according to example 5, in which the non-functional region is between the first replica region and the second replica region.

Example 7 provides the IC device according to any one of examples 1-6, further including a third functional region including third semiconductor devices, a third semiconductor device having a third logic or storage function; and an additional replica region including one or more second semiconductor devices of the second functional region and one or more third semiconductor devices of the third functional region, in which the additional replica region is between the second functional region and the third functional region.

Example 8 provides the IC device according to any one of examples 1-7, in which a height of the replica region is no more than approximately 2 micrometers.

Example 9 provides the IC device according to any one of examples 1-8, in which the replica region abuts the first functional region.

Example 10 provides a method of forming an IC device, the method including determining a first region between a first functional region and a second function region, the first functional region including first semiconductor devices having a first logic or storage function, the second functional region including second semiconductor devices having a second logic or storage function;

determining a second region between the first functional region and the second functional region, in which the first functional region is closer to the first region than to the second region; replicating one or more first semiconductor devices of the first functional region into the first region; and providing filler cells in the second region.

Example 11 provides the method according to example 10, in which replicating the one or more first semiconductor devices of the first functional region into the first region includes identifying the one or more first semiconductor devices, in which the one or more first semiconductor devices are in logic cells or memory cells; and replicating the logic cells or memory cells into the first region.

Example 12 provides the method according to example 10 or 11, in which determining the second region includes providing a grid over an area including the first function region and the second function region, the grid including units in rows and columns; identifying one or more first units in the grid that are over an edge of the first functional region; identifying one or more second units in the grid that are over an edge of the second functional region; and selecting one or more third units in the grids by excluding the one or more first units and the one or more second units, in which the second region is over the one or more third units.

Example 13 provides the method according to example 12, in which determining the first region includes after determining the second region, identifying a region between the first function region and the second region as the first region.

Example 14 provides the method according to any one of examples 10-13, further including determining a division boundary between the second functional region and a third function region, the third functional region including third semiconductor devices having a third logic or storage function; replicating one or more second semiconductor devices of the second functional region into a region between the second functional region and the division boundary; and replicating one or more third semiconductor devices of the third functional region into a region between the third functional region and the division boundary.

Example 15 provides the method according to any one of examples 10-14, further including determining a third region between a first functional region and a second function region, in which the second functional region is closer to the third region than to the second region; and replicating one or more second semiconductor devices of the second functional region into the third region.

Example 16 provides the method according to any one of examples 10-15, in which determining the first region includes determining a height of a standard cell in the first functional region; and determining a height of the first region based on the height of the standard cell, in which the height of the first region is the same or substantially similar as the height of the standard cell.

Example 17 provides an IC device, including a first block including first functional cells; a second block including second functional cells; a third block including a replica of one or more first functional cells in the first block; and a fourth block including filler cells, in which a first functional cell or a second functional cell is a logic cell or a memory cell, the third block is between the first block and the fourth block, the fourth block is between the second block and the third block.

Example 18 provides the IC device according to example 17, further including a fifth block including fifth functional cells, in which a functional cell is a logic cell or a memory cell; a sixth block including a replica of one or more of the fifth functional cells in the fifth block; and a seventh block including a replica of one or more second functional cells in the second block, in which the sixth block and the seventh block are between the second block and the fifth block, the one or more second functional cells are at an edge of the second block, and the one or more of the fifth functional cells are at an edge of the fifth block.

Example 19 provides the IC device according to example 17 or 18, further including a fifth block that includes a replica of one or more second functional cells in the second block, in which the fifth block is between the second block and the fourth block, and the one or more second functional cells are at an edge of the second block.

Example 20 provides the IC device according to any one of examples 17-19, in which a height of the third block is the same or substantially similar as a height of a first functional cell.

Example 21 provides an IC package, including the IC device according to any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first functional region comprising first semiconductor devices, a first semiconductor device having a first logic or storage function;
a second functional region comprising second semiconductor devices, a second semiconductor device having a second logic or storage function;
a replica region comprising one or more first semiconductor devices of the first functional region; and
a non-functional region,
wherein the replica region and the non-functional region are between the first functional region and the second functional region, the first functional region is closer to the replica region than to the non-functional region.

2. The IC device according to claim 1, wherein the first semiconductor devices are in standard cells.

3. The IC device according to claim 2, wherein a height of the replica region is the same or substantially similar as a height of a standard cell.

4. The IC device according to claim 3, wherein the standard cell comprises conductive structures stacked in a first direction, and the height of the standard cell is a dimension of the standard cell in a second direction that is perpendicular to the first direction.

5. The IC device according to claim 1, wherein:
the replica region is a first replica region,
the IC device further comprises a second replica region that includes one or more second semiconductor devices of the second functional region, and
the second functional region is closer to the second replica region than to the non-functional region.

6. The IC device according to claim 5, wherein the non-functional region is between the first replica region and the second replica region.

7. The IC device according to claim 1, further comprising:
a third functional region comprising third semiconductor devices, a third semiconductor device having a third logic or storage function; and
an additional replica region comprising one or more second semiconductor devices of the second functional region and one or more third semiconductor devices of the third functional region,
wherein the additional replica region is between the second functional region and the third functional region.

8. The IC device according to claim 1, wherein a height of the replica region is no more than approximately 2 micrometers.

9. The IC device according to claim 1, wherein the replica region abuts the first functional region.

10. A method of forming an integrated circuit (IC) device, the method comprising:
determining a first region between a first functional region and a second function region, the first functional region comprising first semiconductor devices having a first logic or storage function, the second functional region comprising second semiconductor devices having a second logic or storage function;
determining a second region between the first functional region and the second functional region, wherein the first functional region is closer to the first region than to the second region;
replicating one or more first semiconductor devices of the first functional region into the first region; and
providing filler cells in the second region.

11. The method according to claim 10, wherein replicating the one or more first semiconductor devices of the first functional region into the first region comprises:
identifying the one or more first semiconductor devices, wherein the one or more first semiconductor devices are in logic cells or memory cells; and
replicating the logic cells or memory cells into the first region.

12. The method according to claim 10, wherein determining the second region comprises:
providing a grid over an area comprising the first function region and the second function region, the grid comprising units in rows and columns;
identifying one or more first units in the grid that are over an edge of the first functional region;
identifying one or more second units in the grid that are over an edge of the second functional region; and
selecting one or more third units in the grids by excluding the one or more first units and the one or more second units,
wherein the second region is over the one or more third units.

13. The method according to claim 12, wherein determining the first region comprises:
after determining the second region, identifying a region between the first function region and the second region as the first region.

14. The method according to claim 10, further comprising:
determining a division boundary between the second functional region and a third function region, the third functional region comprising third semiconductor devices having a third logic or storage function;
replicating one or more second semiconductor devices of the second functional region into a region between the second functional region and the division boundary; and
replicating one or more third semiconductor devices of the third functional region into a region between the third functional region and the division boundary.

15. The method according to claim 10, further comprising:
determining a third region between a first functional region and a second function region, wherein the second functional region is closer to the third region than to the second region; and
replicating one or more second semiconductor devices of the second functional region into the third region.

16. The method according to claim 10, wherein determining the first region comprises:
determining a height of a standard cell in the first functional region; and
determining a height of the first region based on the height of the standard cell,
wherein the height of the first region is the same or substantially similar as the height of the standard cell.

17. An integrated circuit (IC) device, comprising:
a first block comprising first functional cells;
a second block comprising second functional cells;
a third block comprising a replica of one or more first functional cells in the first block; and
a fourth block comprising filler cells,
wherein a first functional cell or a second functional cell is a logic cell or a memory cell, the third block is between the first block and the fourth block, the fourth block is between the second block and the third block.

18. The IC device according to claim 17, further comprising:
a fifth block comprising fifth functional cells, wherein a functional cell is a logic cell or a memory cell;
a sixth block comprising a replica of one or more of the fifth functional cells in the fifth block; and
a seventh block comprising a replica of one or more second functional cells in the second block,
wherein the sixth block and the seventh block are between the second block and the fifth block, the one or more second functional cells are at an edge of the second block, and the one or more of the fifth functional cells are at an edge of the fifth block.

19. The IC device according to claim 17, further comprising:
a fifth block that includes a replica of one or more second functional cells in the second block,
wherein the fifth block is between the second block and the fourth block, and the one or more second functional cells are at an edge of the second block.

20. The IC device according to claim 17, wherein a height of the third block is the same or substantially similar as a height of a first functional cell.
